(19) United States
(12) Patent Application Publication
(10) Pub. No.: US 2014/0091379 A1
(43) Pub. Date: Apr. 3, 2014

(54) FLUOROCARBON COATING HAVING LOW REFRACTIVE INDEX

(71) Applicant: Applied Materials, Inc., Santa Clara, CA (US)

(72) Inventors: Sum-Yee Betty TANG, Cupertino, CA (US); Martin SEAMONS, San Jose, CA (US)

(73) Assignee: Applied Materials, Inc., Santa Clara, CA (US)

(21) Appl. No.: 14/040,629

(22) Filed: Sep. 28, 2013

Related U.S. Application Data
(60) Provisional application No. 61/708,608, filed on Oct. 1, 2012.

(51) Int. Cl. C09D 5/00; H01L 27/146; H01L 31/0216

(52) U.S. Cl. CPC C09D 5/006; H01L 31/02162; H01L 27/1462
USPC 257/294; 570/134; 568/683; 427/569; 257/435; 438/72

(57) ABSTRACT

A fluorocarbon coating comprises an amorphous structure with CF₂ bonds present in an atomic percentage of at least about 15%, and having a refractive index of less than about 1.4. The fluorocarbon coating can be deposited on a substrate by placing the substrate in a process zone comprising a pair of process electrodes, introducing a deposition gas comprising a fluorocarbon gas into the process zone, and forming a capacitively coupled plasma of the deposition gas by coupling energy to the process electrodes.

### CROSS-REFERENCE

The present application claims priority to Provisional Application No. 61/708,608, filed Oct. 1, 2013, which is incorporated by reference herein and in its entirety.

### BACKGROUND

Embodiments of the present invention relate to a low-refractive index coating, coating applications, and methods of fabrication.

Low refractive index coatings are used as anti-reflective (AR) coatings for coating photo-active features of a photo-active device such as a pixel sensor, image sensor or display, to reduce glare and surface reflectance. An AR coating is an optical coating applied to improve the efficiency of a sensing, imaging or display system, by reducing the loss of incident radiation such as light. AR coatings increase the transmission of visible light through the photo-active device by reducing surface, interface, and multiple surface reflectance losses to enhance light transmittance and image quality. For example, AR coatings can reduce reflections to improve the contrast of the image by eliminating stray light. AR coatings can also be used to coat polarizing films to reduce internal reflected light. AR coatings are often made from a transparent thin film having a relatively low refractive index. The low-refractive film produces destructive interference in the beams reflected from the interfaces, and constructive interference in the corresponding transmitted beams.

AR coatings can be applied to an image sensor such as a photodetector, optical interconnect, camera, vision and guidance system, navigation system, automotive applications, and consumer products. For example, AR coatings are applied on microelectronic image sensors such as Complementary Metal-Oxide Semiconductor (CMOS) systems, Charged Coupled Device (CCD) arrays, and other solid-state systems. In CCD arrays, pixels are represented by p-doped MOSFET capacitors, and such sensors are often used in digital cameras. CMOS image sensors are active pixel sensors made by CMOS semiconductor processes and as such, can have lower fabrication costs than CCD arrays. In CMOS image sensors each photo sensor converts light energy to a voltage signal, and optionally, converts the voltage signal to digital data, or otherwise processes the image or voltage signal to generate a processed output signal. Active pixel sensors have transistors within each pixel cell, and can be arranged as a pixel array with columns. AR coatings can also be applied to displays such as liquid crystal displays, plasma television displays, PC monitors, portable computer screens, PDAs, electronic game displays, scoreboards and marquis.

The efficiency of an AR coating is often determined by the value of its refractive index. For example, an AR coating is used to coat a lens of a complementary metal oxide semiconductor (CMOS) image sensor to reduce reflectance and increase the light transmittance and image quality of the sensor. However, AR coatings fabricated using semiconductor processing, such as silicon dioxide films, have a refractive index of 1.46 which only reduces surface reflectivity from about 5% without the coating to about 3% with the coating. Lower refractive index AR coatings are difficult to achieve with conventional silicon dioxide films at temperatures below 200° C. as required for many CMOS sensor devices. While low refractive index AR coatings can also be formed by sequentially deposited a series of high and low refractive index films, the efficiency of such multi-layer coatings is limited by the value of the low refractive index film component. Transparent films having a low refractive index would generate more efficient anti-reflective AR coatings.

AR coatings having a low refractive index have been fabricated using conventional wet-processing methods such as spin coating. For example, AR coatings made from materials such as Teflon have been made with refractive indices of less than 1.4. However, in spin coating, a liquid polymer precursor is spun in the liquid state on to the imaging or display device, followed by baking and curing at temperatures that exceed 400° C. to polymerize and dry the liquid precursor and remove solvent. At these relatively high temperatures, the internal features of the imaging or display device deteriorate resulting in lower yields and higher fabrication costs. Also, spin coating is used to deposit only planarized films, while conformal deposition on non-planar surfaces is often required for AR coating over imaging features like microlenses. As a result, wet processed and spin coated coatings have limited applications and cannot be used for many types of image sensors and displays.

For various reasons that include these and other deficiencies, and despite the development of low refractive index coatings use for anti-reflective applications and their deposition methods, further improvements in such coatings are continuously being sought.

### SUMMARY

A fluorocarbon coating comprises an amorphous structure with CF₂ bonds present in an atomic percentage of at least about 15%, and having a refractive index of less than about 1.4.

A coated photo-active device comprises a photo-active feature and a fluorocarbon coating overlying the photo-active feature. The fluorocarbon coating comprises an amorphous structure with CF₂ bonds present in an atomic percentage of at least about 15%, and having a refractive index of less than about 1.4.

A CMOS image sensor comprises a substrate, a photo-active feature on the substrate, one or more metal features about the photo-active feature, a lens overlying the photo-active feature, and a fluorocarbon coating on the lens.

A CMOS image sensor comprises a substrate, an array of photo-active features on the substrate, twin stacks of metal features about each of the photo-active features, a color filter array comprising at least three different color filters disposed over the photo-active features, a plurality of lenses, each lens overlying a color filter, and a fluorocarbon coating on each lens.

A method of depositing a fluorocarbon coating on a photo-active feature on a substrate, comprises forming a substrate having a plurality of photo-active features thereon, placing the substrate in a process zone comprising a pair of process electrodes, introducing a deposition gas comprising a fluorocarbon gas into the process zone, and forming a capacitively coupled plasma of the deposition gas by coupling energy to the process electrodes in the process zone to deposit the fluorocarbon coating on the substrate.

### DRAWINGS

These features, aspects and advantages of the present invention will become better understood with regard to the following description, appended claims and accompanying drawings, which illustrate examples of the invention. However, it is to be understood that each of the features can be used in the invention in general, not merely in the context of the particular drawings, and the invention includes any combination of these features, where:

FIG. 1 is a schematic cross-sectional view of a fluorocarbon coating deposited on photo-active features of a photo-active device formed on a substrate;

FIG. 2A is a schematic cross-sectional view of a photo-active device comprising a photo-active feature that is a front-illuminated CMOS image sensor composed of an array of three photodiodes that each have a different color filter and a microlens with a fluorocarbon coating thereon;

FIG. 2B is a schematic cross-sectional view of a photo-active device comprising a photo-active feature that is a back-illuminated CMOS image sensor;

FIG. 2C is a schematic cross-sectional view of a photoactive device comprising a photodiode;

FIG. 2D is a schematic cross-sectional view of another embodiment of a photodiode;

FIG. 3 is a flow chart of an exemplary process for the deposition and treatment of a fluorocarbon coating on a substrate;

FIG. 4 is a graph of an X-ray Photoelectron Spectroscopy (XPS) spectra of the fluorocarbon coating showing the different carbon-fluorine bonds present in the coating;

FIG. 5 is a bar graph of the F/C ratio determined by XPS for the four different fluorocarbon coating specimens A, B, C and D, which were each deposited with different deposition gases;

FIG. 6 is a graph of the F/C ratio and atomic percentage of C—F₂ bonds versus measured refractive index for the four different fluorocarbon coating specimens;

FIG. 7 is a graph of a Fourier Transformed Infrared Spectroscopy (FTIR) spectra of the fluorocarbon coating showing a broad absorbance band at wavelengths of 1100 to 1400 cm-1 that indicates an amorphous structure; and

FIG. 8 is a schematic view of an embodiment of a substrate processing chamber comprising a plasma enhanced chemical vapor deposition (PECVD) chamber having a remote plasma chamber for cleaning gas.

### DESCRIPTION

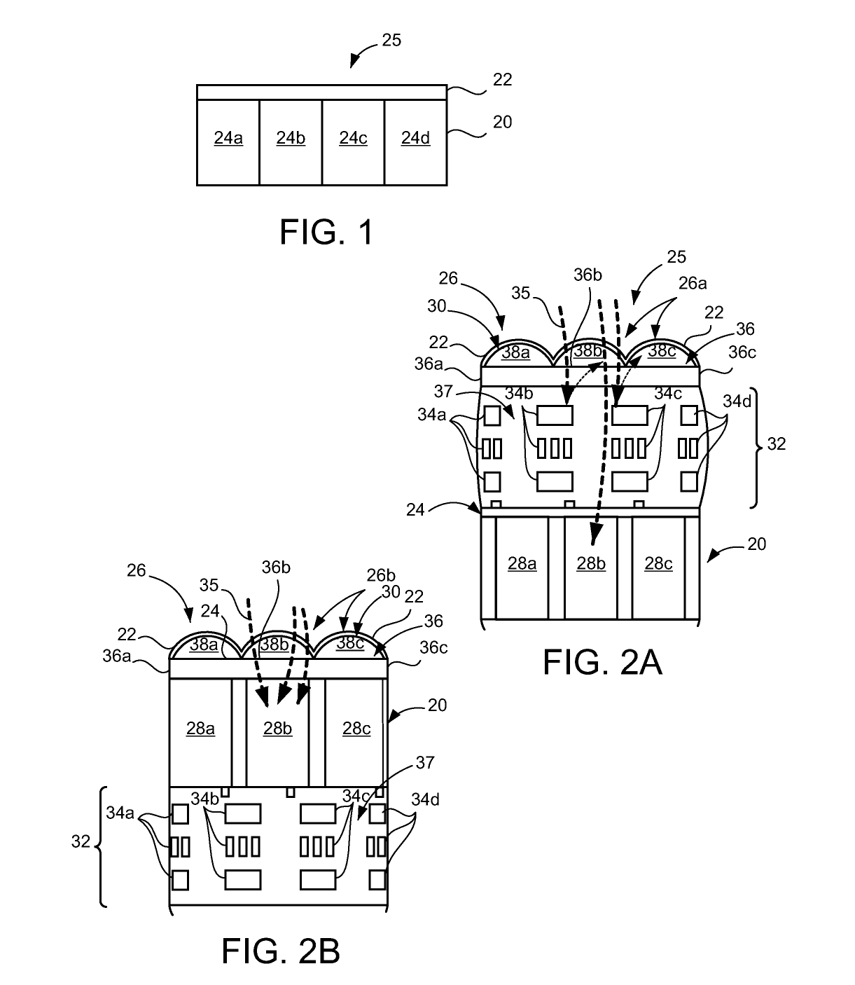

A fluorocarbon coating 22 that serves as an anti-reflective coating overlying a photo-active feature 24 of a photo-active device 25, as shown in FIG. 1, is deposited on a substrate 20 at low temperatures by plasma enhanced chemical vapor deposition (PECVD). While “coating” is used to describe the fluorocarbon PECVD deposits, it should be understood that by coating it is meant any one of a continuous layer, a discontinuous layer, selective deposition on underlying features, and deposition of a layer followed by the etching of portions of the deposited layer. Further, the fluorocarbon coating 22 can be deposited directly on the photo-active device 25, or more typically, on other features overlying the photo-active device 25, such as for example, a lens or window.

The substrate 20 can be, for example, a silicon wafer, a wafer of a III-V compound such as gallium arsenide, a germanium or silicon-germanium (SiGe)e wafer, an epi-substrate, a silicon-on-insulator (SOI) substrate, a display such as a liquid crystal display (LCD), a plasma display, an electroluminescence (EL) lamp display, or a light-emitting diode (LED) substrate. In certain applications, the substrate 20 may be a semiconductor wafer such as a silicon wafer having a diameter of 200 mm, 300 mm, or even 450 mm. In other applications, the substrate 20 can be a dielectric plate, such as polymer or glass panel, e.g., acrylics, polyimide, and borosilicate and phosphosilicate glass panels.

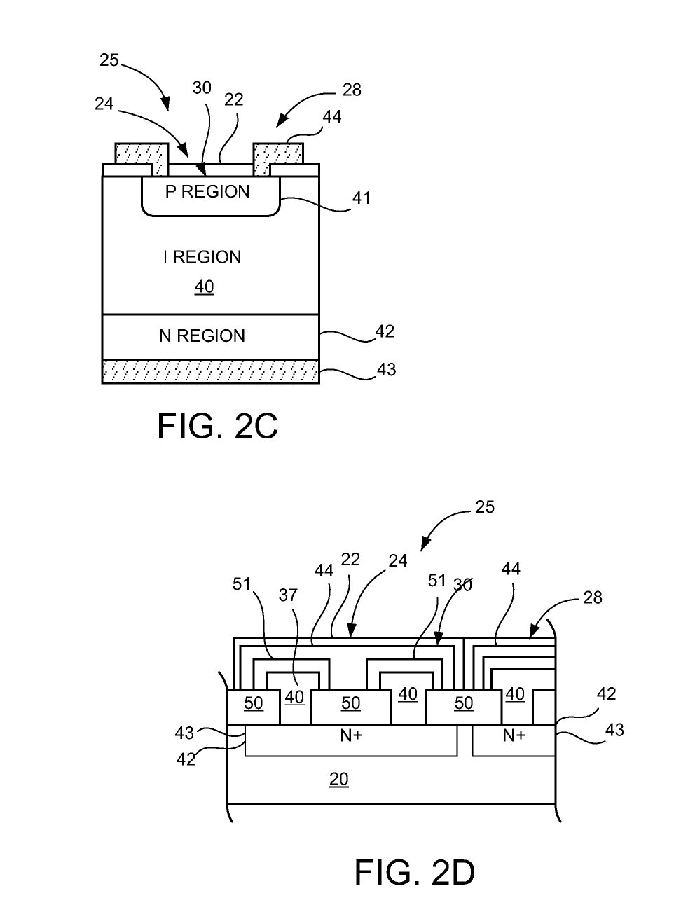

The photo-active device 25 can include one or more photo-active features 24 which can be, for example, image sensors or display pixels. For example, FIG. 2A shows a photo-active device 25 comprising a photo-active feature 24 that is a complementary metal-oxide semiconductor (CMOS) image sensor 26. In this version, the image sensor 26a comprises a front-illuminated CMOS image sensor 26a having an image receiving surface 30. The image sensor 26a comprises an array of three photodiodes 28a-c formed in a substrate 20 that is a silicon wafer. Each of the photodiodes 28a-c converts to electrons, radiation such as light, which is incident on the image receiving surface 30 and which passes through to reach the photodiodes. A metal layer 32 comprises stacks of one or more metal features 34a-d aligned with the photodiodes 28a-c. The metal features 34a-d can serve as, for example, electrodes, guard rings and light gates. For example, in the version shown, twin stacks of adjacent metal features 34a,b or 34b,c or 34c,d are aligned along the light pathway, and positioned overlying, the three photodiodes 28a-c. A color filter array 36 comprises at least three color filters 36a-c, for example, a red filter (36a), blue filter (36b), and green filter (36c). Each of the color filters 36a-c are aligned along a light pathway of one of the photodiodes 28a-c. A lens 38a-c covers each color filter 36a-c and is also aligned to, and overlying, a photo-active feature 24, namely one of the photodiodes 28a-c.

A fluorocarbon coating 22 covers the image-receiving surface 30 of the image sensors 26. In this version, the fluorocarbon coating 22 covers the surfaces of the lenses 38a-c to serve as an anti-reflective coating. The AR coating reduces light reflectivity arising from the mismatched in refractive indexes between air (RI_{AIR}=1) and the lenses 38a-c (RIₗₑₙₛ which is typically from 1.5 to 1.8). The optimal refractive index for the fluorocarbon coating 22 can be determined from the formula RI_{COATING}=(RI_{AIR}*RIₗₑₙₛ)^{1/2}. The optimal refractive index minimizes reflection and maximizes transmission at the lens-air interface, at a selected light wavelength, for example, at wavelengths of from about 400 to about 700 nm. Without the fluorocarbon coating 22, surface reflection of the incident light intensity can be 5% or even higher. With a fluorocarbon coating 22 having an RI_{COATING} of less than about 1.4, the surface reflection was found to be reduced to less than 3% or even less than 2%.

As another example, FIG. 2B shows a photo-active device 25 comprising a photo-active feature 24 that is also an image sensor 26 comprising a back-illuminated CMOS image sensor 26b. In this version, the image sensors 26b each include an underlying metal layer 32 comprising stacks of the metal features 34a-c. The substrate 20 is, for example, a silicon wafer that is thinned to less than 20 microns. The metal layer 32 is covered by an array of three photodiodes 28a-c which is formed in a substrate 20. A color filter 36 comprising a plurality of color filters 36a-c is formed over the image receiving surface 30. The color filters 36a-c can comprise, for example, red, green and blue filters. A lens 38a-c covers each of the color filters 36a-c of the photodiodes 28a-c. The fluorocarbon coating 22 covers the image receiving surface 30 which is the surfaces of the lenses 38a-c to serve as an anti-reflective coating for the image sensor 26b.

An exemplary embodiment of a photo-active device 25 comprising a photo-active feature 24 that is a photodiode 28 is illustrated FIG. 2C. The photodiode 28 generally comprises a P-N junction which are can be a P-I-N or N-I-P junction, which have a thicker, middle, intrinsic region (I-region) 40 between the P-region 41 and N-region 42. The intrinsic region 40 is where most of the incident photons are absorbed to generate carriers that efficiently contribute to the photocurrent. The intrinsic region 40 may be either completely undoped or lightly doped, such as doped to form a lightly doped N-region. The photodiode 28 comprises (i) an underlying bottom electrode 43, (ii) a N-region 42 overlying the bottom electrode, (iii) an I-region 40 over the N-region 42, (iv) a P-region 41 embedded into the I-region 40, (v) a top electrode 44 contacting the P-region 41, and (v) a fluorocarbon coating 22 over the image receiving surface 30 of the P-region 41, which serves as an anti-reflective coating for incident radiation such as optical light, infrared or ultraviolet radiation. In another version, the photodetector 28 can also be an avalanche photodiode, which has a similar structure to that of the more commonly used PN/PIN/NIP structures. However, as the avalanche photodiode is operated under a high level of reverse bias with a guard ring (not shown) placed around the perimeter of the PN/PIN/NIP junction to reduce or prevent surface breakdown mechanisms.

The materials used to fabricate the photodiode 28 determine its light sensitive properties, namely, the wavelength of light to which the photodiode responds and the signal to noise ratio. The wavelength sensitivity occurs because only photons with sufficient energy to excite an electron across the bandgap of the material will produce significant energy to develop a current from the photodiode 28. For example, the wavelength sensitivity of germanium is from about 800 to about 1700 nm, indium gallium arsenide is from about 800 to about 2600 nm, lead sulphide is from about to about 3005 nm, and of silicon is from about 190 about 1100 nm.

Another exemplary structure of a photodiode 28 comprising a P-I-N structure is illustrated in FIG. 2D. This photodiode 28 includes (i) one or more bottom electrodes 46 which also serve as the N-regions 44, and which can be N⁺ features composed of a semiconducting material implanted with N⁺ ions, (ii) spaced-apart dielectric features 50 that overlie adjacent N⁺ features to form the separation gaps 37, (iii) an intrinsic region 40 comprising lightly N+-doped material that fills and covers the gaps 37 between the dielectric features 50, (iv) P-regions 42, such as P⁺ regions, comprising a doped semiconducting material, (v) one or more top electrodes 48, and (vi) a fluorocarbon coating 22 covering the image receiving surface 30 of the photodiode 28. The N-regions 44, are formed, for example, in a silicon wafer and are composed of portions of the silicon wafer implanted with N+ ions, such as phosphorous, by conventional ion implantation processes. The dielectric features 50 are formed by depositing a silicon dioxide layer by CVD, planarizing the silicon dioxide layer with chemical mechanical polishing, and then etching holes into the silicon dioxide layer to form the gaps 37 between the features 50 with conventional photolithography and etching methods. The intrinsic regions 40 lightly N+ doped material can be CVD deposited polysilicon ion implanted with phosphorous. The P+ regions 42 can be for example, silicon, polysilicon or germanium, doped with boron or aluminium by ion implantation. The top electrodes 48 can be made from conducting material, such as polysilicon or indium tin oxide (In₂O₃—SnO₃-ITO). The structure and fabrication method as described are suitable for P-I-N photodiodes; however, the same method can be used to fabricate N-I-P photodiodes by simply changing the n-doped and p-doped layers to p-doped and n-doped layers, respectively.

The photo-active device 25 can also be an active-pixel sensor (APS) comprising photo-active features 24 each of which include an image sensor 26 composed of an integrated circuit containing an array of pixel sensors. Each pixel sensor contains a photodiode and an active amplifier. Common active pixel sensors include the CMOS APS used most commonly in cameras such as cell phone cameras, web cameras and in some DSLRs. The pixel sensors are also produced by conventional CMOS processes, and consequently, also known as CMOS sensors.

For any of the versions of photo-active devices 25 described herein, a fluorocarbon coating 22 is positioned in the light passageway leading to a photo-active feature 24. For example, the fluorocarbon coating 22 can be deposited on the lenses 38a-c of the front and back-illuminated CMOS image sensors 26a,b, respectively, as shown in FIGS. 2A and 2B. As another example, the fluorocarbon coating 22 can be deposited on the imaging surface of photo-active features 24 which are display pixels. In yet another example, the fluorocarbon coating 22 can be deposited on the light-receiving surface of photo-active features 24 comprising active-pixel sensors.

The fluorocarbon coating 22 has an amorphous structure with a composition comprising elemental carbon and fluorine. Generally, the fluorocarbon coating 22 has the composition CₓF_{y} with the presence of any one or more of CF, CF₂, CF₃, and C—CF bonds as described below. In one version, the fluorocarbon coating 22 also has CF₂ bonds present in an atomic percentage of at least about 15%, or even at least about 20%. The carbon to fluorine ratio and the percentage of CF₂ bonds was found to be determinative of the refractive index of the fluorocarbon coating 22 as explained below. In one version, the fluorocarbon coating 22 has the structure CₓF_{y}, where the ratio of (y:x) is from about 1 to about 2, or even from about 1.4 to about 2. The fluorocarbon coating 22 also has a refractive index of less than about 1.4, or even from about 1.375 to about 1.4, at wavelengths of visible light, such as wavelengths of from about 400 to about 700 nm.

In one exemplary structure, the fluorocarbon coating 22 was deposited on CMOS image sensors 26 as described above, which had pixel sizes of about 1.4 microns or larger. After deposition of the fluorocarbon coating 22 on the image-receiving surfaces 30 of the image sensors 26, the surface reflection of incident light from the surfaces of the lenses 38a—was determined to be less than about 2% at wavelengths of from about 400 to about 700 nm. The reflectivity of the lenses 38a-c was determined using the refractive index of the lens material. The light transmission results demonstrated that the light transmittance through the lens of the photo-active sensor increased by from about 3% to about 5% with the applied fluorocarbon coating 22. The light transmission of the fluorocarbon coating 22 was evaluated from the signal to noise ratio at each pixel color Still further, a quantum efficiency (QE) gain of from about 2% to about 3% was observed for the fluorocarbon coating. The signal to noise ratio was also observed to have increased in all three pixel colors. These results represented significant improvements over prior art anti-refractive coatings, such as silicon dioxide coatings.

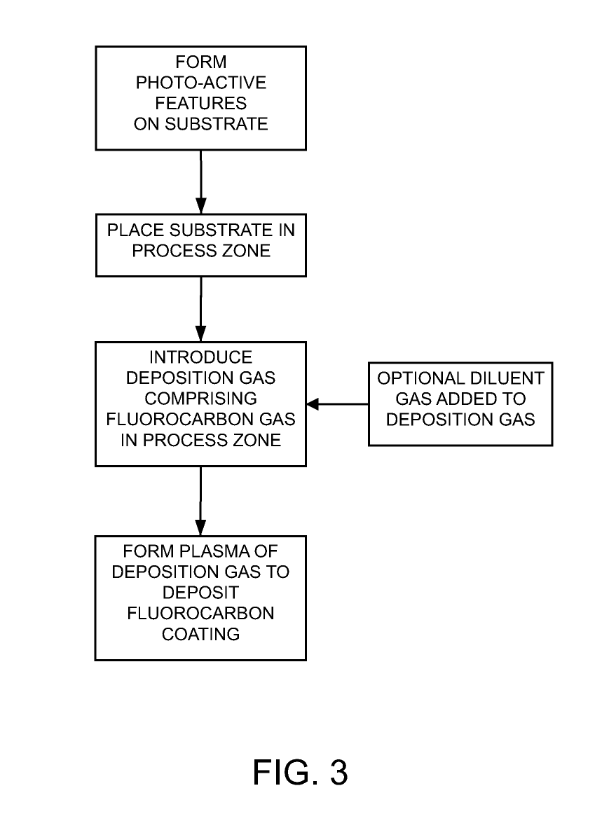

In an exemplary fabrication process, the fluorocarbon coating 22 is deposited on the substrate 20 by a plasma enhanced chemical vapor deposition (PECVD) process, as illustrated in the flowchart of FIG. 3. Conventional wet-processing methods require baking a spin-coated AR coating at temperatures at or exceeding 400° C. which result in deterioration of the underlying photo-active features because of thermal decomposition during the high temperature baking process. In contrast to conventional wet-processing methods, the PECVD process did not cause deterioration of the underlying photo-active features 24 as the deposition process can be conducted at temperatures of less than about 240° C.

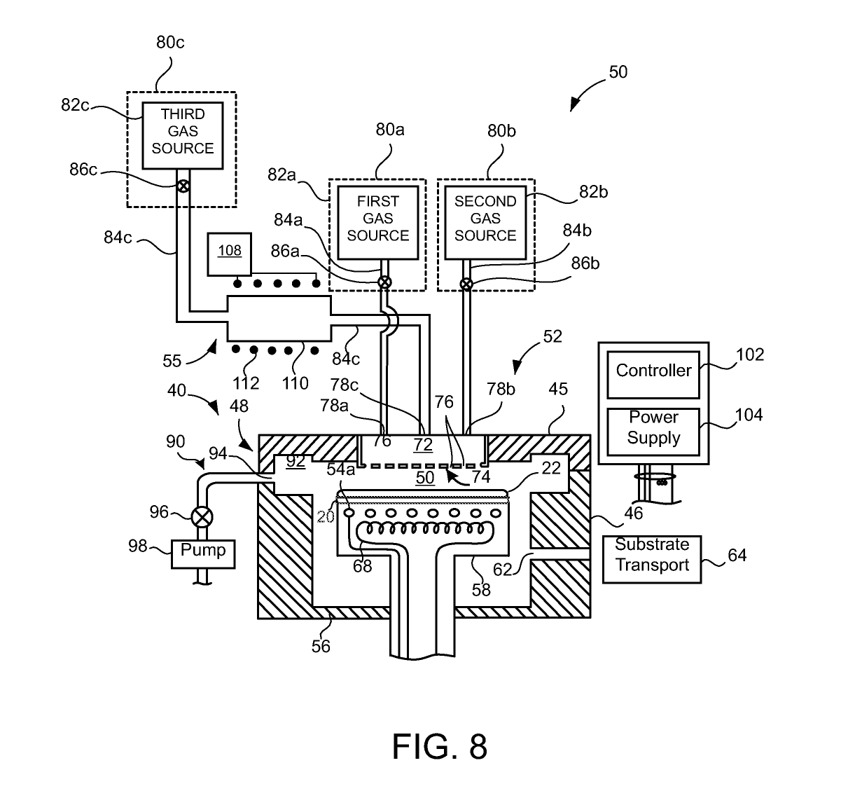

In the deposition process, a substrate 20 comprising one or more photo-active features 24 is processed in a substrate processing apparatus 50 by placing the substrate 20 in a process zone 51 of a process chamber 52 of the apparatus 50. An exemplary embodiment of a suitable apparatus 50 and process chamber 52 is shown in FIG. 8. During deposition, the substrate 20 is maintained at a temperature of less than about 240° C., or even from about 80° C. to about 200° C., or even about 40° C. These low temperatures are particularly advantageous as they do not thermally degrade the photo-active features 24 of the substrate 20.

A deposition gas comprising a fluorocarbon gas is introduced into the process zone 51. The fluorocarbon gas comprises carbon and fluorine in a ratio of carbon to fluorine that is suitable to deposit the fluorocarbon coating 22. In one version, the fluorocarbon gas comprises a carbon to fluorine ratio of from about 1:1 to about 1:3. A fluorocarbon gas having such carbon to fluorine ratios was found to provide fluorocarbon coatings having lower refractive indices. Suitable fluorocarbon gases include, for example, C₄F₈, C₄F₆, C₃F₈, and C₃F₆O. A suitable flow rate for the fluorocarbon gas is from about 50 to about 5000 sccm.

The deposition gas may also include a diluent gas to control the properties of the plasma generated from the fluorocarbon gas of the deposition gas. For example, the diluent gas can improve the deposition uniformity of the fluorocarbon coating 22 by diluting the concentration of carbon and fluorine species in the process chamber 52. The diluent gas can also serve to energize and dissociate the carbon or fluorine atoms of the fluorocarbon gas for reaction via molecular collisions in the process zone 51. Suitable diluent gases can include, for example, argon (Ar), helium (He), and mixtures thereof. The diluent gas is typically provided in a larger volume than the fluorocarbon gas. For example, the diluent gas can be at least one of argon, helium, or an argon-helium mixture. The diluent gas can be added in a flow rate of from about 500 to about 10,000 sccm. The deposition gas is maintained at the pressure into the process zone 51 of the process chamber 52. For example, for the deposition gases described herein, a suitable pressure is from about 0.5 Torr to about 20 Torr, or even 1 Torr to about 10 Torr.

A plasma is formed from the deposition gas by coupling energy to the deposition gas. For example, the plasma can be formed by capacitively coupling energy to the process electrodes 54a,b about the process zone 51 containing the deposition gas. The energy coupled to the electrodes 54a,b has radio frequencies (RF) of from about 1 KHz to about 20 MHz. In one version, a suitable frequency of the RF energy is from about 10 MHz to about 15 MHz (e.g., about 13.6 MHz). In one embodiment, RF energy is capacitively coupled to the deposition gas by biasing a first electrode 54a comprising a ceiling 45 about the process zone 51 and a second electrode 54b in a substrate support 58, as shown in FIG. 8. The process electrodes 54a,b are biased by coupling RF energy to the electrodes 54a,b at a power level of from about 10 to about 2000 W, or even from about 50 to about 750 W. In the exemplary process chamber 52, the process electrodes 54a,b are maintained at an electrode spacing distance of from about 7.5 mm (300 mils) to about 40 mm (1600 mils).

Typically, a number of fluorocarbon coating deposition processes are conducted to coat a plurality of substrates 20 of a batch of substrates, after which, a cleaning process is conducted to clean the interior surfaces of the process chamber 52. A cleaning process can also be conducted between processing steps in which different materials are deposited on a single substrate 20, such as a multilayer anti-reflective coating as described below. In the cleaning process, the substrate 20 is removed from the process zone 51 of the process chamber 52. Thereafter, an energized cleaning gas is introduced into the process zone 51 to clean the interior surfaces of the process chamber 52. In one version, the energized cleaning gas comprises an oxygen-containing gas, such as nitrous oxide (N₂O) or oxygen (O₂). The cleaning gas can be provided in a volumetric flow rate of from about 100 to about 10,000 sccm, or even from about 300 to about 5,000 sccm. The cleaning gas is maintained in the process zone 51 at a pressure of from about 1 to about 10 Torr. The cleaning gas can be energized in the process chamber 52 using the process electrodes 54a,b as described above. In one version, a cleaning gas is energized in a remote gas energizer 55, as shown in FIG. 8, and thereafter, introduced into the process chamber 52. For example, the cleaning gas can be energized in the remote gas energizer 55 by applying a current through the coil, the maximum power of which is 9KW. The cleaning process is typically conducted for about 30 seconds to about 5 minutes.

Before or after the fluorocarbon coating deposition process, other deposition Processes can be used to deposit underlayers or overlayers onto the fluorocarbon coating 22. For example, a multilayer anti-reflective coating can include the fluorocarbon coating 22 and other layers having different refractive indices. Still further, the other layers may include further fluorocarbon coatings of the same type, fluorocarbon coatings having different refractive indices, silicon dioxide coatings, or still other types of coating materials. For example, a first fluorocarbon coating 22 can be covered by, or have an underlayer of, a second coating comprising a silicon dioxide coating having a refractive index of about 1.46. The silicon dioxide coating can be deposited by a CVD process conducted in the same chamber or a different chamber. For example, the silicon dioxide coating can be deposited using a process gas comprising silane (SiH₄) and nitrous oxide (N₂O). In such a process, the silane is provided in a flow rate of from about 10 to about 1000 sccm; nitrous oxide is provided in a flow rate of from about 100 to about 10,000 sccm. The deposition gas is maintained in the process chamber 52 at a pressure of from about 1 to about 10 Torr. The deposition gas is energized by an RF generator. Each layer of silicon dioxide can have a thickness of from about 100 to about 1000 angstrom. The multilayer deposition process can also be repeated a number of times to achieve a multilayer comprising a plurality of fluorocarbon coatings 22 and silicon dioxide coatings. A suitable thickness for the cumulative multilayer anti-reflective coating can be from about 1000 angstroms to about 3000 angstrom.

Still further, while the fluorocarbon coating 22 is illustrated for an anti-reflective coating application, the fluorocarbon coating 22 can also be used for other applications. For example, the fluorocarbon coating 22 can be used as a hydrophobic underlayer for extreme ultra-violet (EUV) lithography. As another example, the fluorocarbon coating 22 can be used as a release layer to facilitate release of MEMS devices and for nano-imprint lithography.

### EXAMPLES

The following examples illustrate the deposition process, structure, and properties of the fluorocarbon coating 22. However, it should be understood that each of the process steps, structural features, and properties of the fluorocarbon coating 22 as described herein, can be used by themselves or in any combination with each other, and not merely as described in a particular example. Thus, the illustrative examples provided herein should not be used to limit the scope of the present invention.

Table I shows a set of fluorocarbon coating deposition process experiments in which four different process gas compositions containing one of C₄F₆, C₄F₈, C₃F₆O, and C₃F₈, were used to deposit the fluorocarbon coating 22 for specimens A, B, C and D, respectively (see also FIG. 5). In this table, spacing is the spacing of the electrodes 54a,b in the chamber, D/R is the fluorocarbon coating deposition rate, R/2% is (maximum thickness− minimum thickness)/mean thickness*50, and RI (refractive index). As seen, the lowest refractive indexes were obtained for specimen D deposited using a process gas comprising C₃F₈ and He—Ar which deposited a fluorocarbon coating 22 having a refractive index of 1.387 at an incident light wavelength of 400 nm, and a refractive index of 1.37 at 633 nm. The deposition processes also deposited a conformal coating at temperatures less than 240° C. Still further, the deposition processes did not damage the temperature sensitive material of the lenses 38a-c of the image sensors 26. Also, the deposition processes were compatible with conventional forces patterning, etching and stripping processes.

TABLE I

| Precursor | C₄F₆ | C₄F₈ | C₃F₆O | C₃F₈ |
|---|---|---|---|---|
| Temperature | 100-200 | 100-200 | 100 | 100 |
| (° C.) | | | | |
| Pressure (Torr) | 5 | 5 | 5 | 10 |
| RF Power (W) | 60 | 500 | 500 | 750 |
| Precursor Flow | 100-1000 | 100-1000 | 100-1000 | 100-1000 |
| (sccm) | | | | |
| Ar—He Flow | 1000-8000 | 1000-8000 | 1000-8000 | 1000-8000 |
| (sccm) | | | | |
| Spacing | 300-1600 | 300-1600 | 300-1600 | 300-1600 |
| (mils) | | | | |
| D/R (A/min) | 273 | 950 | 210 | 204 |
| R/2 % | 3.0 | 2.7 | 20 | 21 |
| RI at 400 nm | 1.4226 | 1.3927 | 1.3904 | 1.387 |
| RI at 633 nm | 1.3967 | 1.3744 | 1.3716 | 1.3688 |

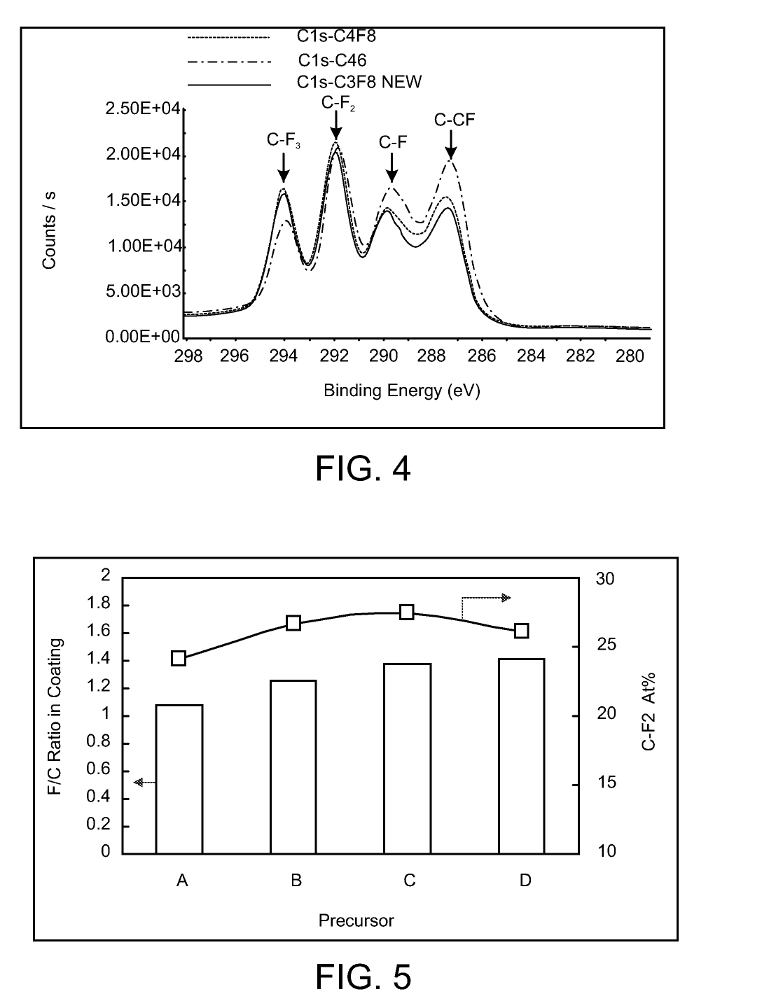

The refractive index of the fluorocarbon coating 22 was correlated to the fluorine (F) to carbon (C) ratio of the precursor gas. X-Ray photoelectron spectroscopy (XPS) data on the fluorocarbon coating 22 show that the F:C ratio of the precursor gas correlated with the F:C ratio present in the deposited fluorocarbon coating 22, as shown in Tables II and III. Generally, the RI_{COATING} value decreased in the order of C₄F₆>C₄F₈>C₃F₆O>C₃F₈. FIG. 4 shows an X-Ray photoelectron spectroscopy (XPS) analysis of the fluorocarbon coating 22. XPS was used to quantitative measure the elemental composition and chemical state of the elements that existed in the fluorocarbon coating 22 by irradiating a sample of the coating with a beam of X-rays in ultra-high vacuum (UHV) conditions while simultaneously measuring the kinetic energy and number of electrons that escaped from the top 1 to 10 nm of the material being analyzed. As seen from the graph, the CF₂ bonds in the fluorocarbon coating 22 which had an intensity peak at about 292 eV appeared be highest when the process gas contained C₃F₆O. However, the presence of CF, C—CF and CF₃ bonds was also detected in the fluorocarbon coating 22.

Table II shows the atomic percentage of different elements for the different fluorocarbon deposition gases. In this Table C1s indicates the presence of carbon element, F1s indicates fluorine element, O1s indicates oxygen element, and F/C indicates the fluorine to carbon (F/C) ratio in the fluorocarbon coating 22. It is seen that the F/C ratio was highest when C₃F₈ was used in the deposition gas. Table III shows the atomic percentage of different bonds present in the fluorocarbon coating 22. As seen, the highest percentage of C—F₂ bonds occurred in the deposition gas contained C₃F₆O.

TABLE II

| At. % | C4F6 | C4F8 | C3F6O | C3F8 |
|---|---|---|---|---|
| C1s | 47.6 | 44.2 | 41.8 | 41.4 |
| F1s | 51.7 | 55.6 | 56.9 | 58.4 |
| O1s | 0.7 | 0.2 | 1.3 | 0.2 |
| F/C | 1.08 | 1.26 | 1.38 | 1.41 |

TABLE III

| At. % | C4F6 | C4F8 | C3F6O | C3F8 |
|---|---|---|---|---|
| C1s-CF | 31.7 | 25.7 | 25.6 | 26 |
| C1s-F | 29.8 | 28.1 | 26.6 | 26.9 |
| C1s-F2 | 24.1 | 26.7 | 27.5 | 26.1 |
| C1s-F3 | 14.5 | 19.5 | 21.4 | 21.1 |

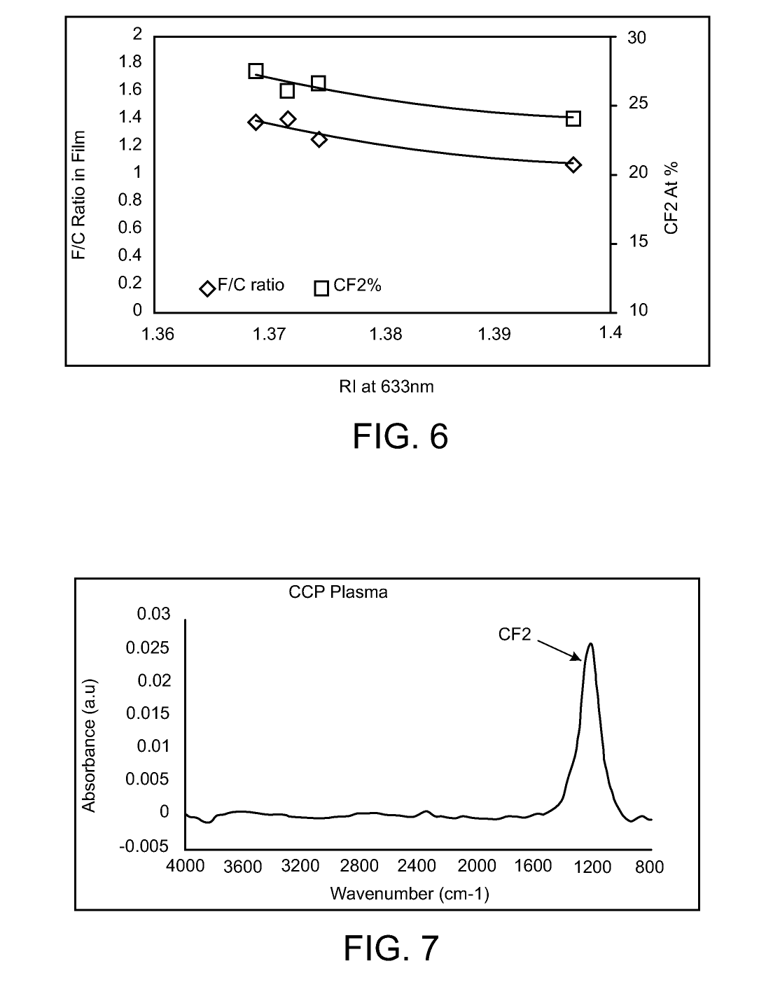

A bar graph of the F/C ratio present in the fluorocarbon coating of specimens A, B, C and D, which were deposited using the previously described deposition gas compositions of Table I, is shown in FIG. 5, and it is seen that the F/C ratio was highest when C₃F₈ was used in the deposition gas. The F/C ratio was also found to be an indicator of the refractive index of the fluorocarbon coating 22. FIG. 6 shows the measured refractive index at a wavelength of 633 nm for the fluorocarbon coatings 22 that had different F/C ratios as listed above. Still further, the F/C ratio can be correlated to the atomic percentage of the C—F₂ bonds in the fluorocarbon coating 22. The higher the F/C ratio and atomic percentage of the C—F₂ bonds in the fluorocarbon coating 22, the lower the resultant refractive index.

Still further, Fourier Transformed Infrared Spectroscopy (FTIR) is also conducted on the fluorocarbon coating 22 as shown in FIG. 7. FTIR was used to obtain an infrared spectrum of the absorption of infrared wavelengths into the fluorocarbon coating 22. The FTIR graph indicated a broad absorbance band at wavelengths of 1100 to 1400 cm-1, which demonstrated that the fluorocarbon coating 22 had a substantially amorphous structure.

### Deposition Apparatus

The coating deposition processes described above can be performed in a substrate processing apparatus 50, an exemplary embodiment of which is illustrated in FIG. 8. The substrate processing apparatus 50 is provided to illustrate an exemplary deposition apparatus; however, other deposition apparatus may also be used as would be apparent to one of ordinary skill in the art. Accordingly, the scope of the invention should not be limited to the exemplary deposition apparatus described herein. Generally, the substrate processing apparatus 50 comprises one or more chemical vapor deposition chambers 52 suitable for processing a substrate 20 such as a silicon wafer or display. A suitable apparatus is a Producer®—DARC, GT or SE type apparatus from Applied Materials, Santa Clara, Calif. The PRODUCER apparatus has two isolated process chambers, as for example, described in U.S. Pat. No. 5,855,681, which is incorporated by reference herein in its entirety. However, a single chamber is shown in FIG. 8 to avoid repeating descriptions of similar features of multiple chambers. Also the process chamber 52 may be one of a number of substrate processing systems that are coupled to a semiconductor substrate processing platform such as a CENTURA® processing platform, available from Applied Materials, Inc.

As shown, the apparatus comprises a process chamber 52 having enclosure walls 48, which include a ceiling 45, sidewalls 46, and a bottom wall 56, that enclose a process zone 51. The ceiling 45 can be dome shaped as shown, and fabricated from a dielectric material such as quartz, aluminum oxide or other ceramic materials. The process chamber 52 may also comprise a liner (not shown) that lines at least a portion of the enclosure walls 48 about the process zone 51. For processing a substrate 20 comprising a 300 mm silicon wafer, the process chamber 52 can have a volume of from about 20,000 to about 30,000 cm³. It is also contemplated that the processing methods described herein may be practiced in other suitably adapted chambers, including those from other manufacturers.

During a process cycle, the substrate support 58 is lowered, and a substrate 20 is passed through an inlet port 62 of the process chamber 52 and placed on the support 58 by a substrate transport 64, such as a robot arm. The substrate support 58 can include an electrode 54a to generate a plasma from process gas introduced into the process chamber 52. For example, the substrate support 58 can be a ceramic structure with the electrode 54a embedded therein or a metal pedestal that serves as electrode 54a. The substrate 20 is retained on the substrate receiving surface of the substrate support 58 during processing. The electrode 54a can also be used to electrostatically clamp the substrate 20 to the support 58 by applying a DC voltage to the electrode 54a. Alternatively, the substrate support 58 can include vacuum chuck or other holding device. The substrate support 58 may also comprise one or more rings, such as deposition rings and cover rings (not shown), that at least partially surround a periphery of the substrate 20 on the support 58.

The substrate support 58 can also be heated by heater 68, which can be an electrically resistive heating element embedded in the substrate support (as shown), a heating lamp underneath the support 58 (not shown), or the plasma itself. In these processes, the substrate temperature can be controlled, for example, using the heater 68 (which can also be a chiller) or by supplying a heat transfer fluid to a fluid conduit heat exchanger (not shown) in the substrate support 58, to heat or cool the substrate 20.

The substrate support 58 can be moved between a lower position for loading and unloading and an adjustable upper position for processing of the substrate 20. For example, after a substrate 20 is loaded onto the substrate support 58 for deposition of a fluorocarbon coating 22, the substrate support 58 is raised to a processing position that is closer to the gas distributor 72 to provide a desired spacing gap distance the distance between the bottom surface of a gas distributor 72 which serves as a second electrode 54b, along with the first electrode 54a in the substrate support 58 The electrode gap distance can be set to be from about 7 mm (about 300 mils) to about 40 mm (about 1600 mils).

The substrate processing process chamber 52 also comprises a gas distributor 72 to mix and deliver a process gas to the process chamber 52. The gas distributor comprises a showerhead having spaced apart gas holes, and is located above the process zone 51 for dispersing a process gas uniformly across the substrate 20. The gas distributor 72 can deliver a process gas comprising two independent streams of first and second gases to the process zone 51 without mixing the gas streams prior to their introduction into the process zone 51. The gas distributor 72 can also premix gases before providing the premixed gases to the process zone 51. The gas distributor 72 comprises a faceplate 74 having holes 76 that allow the passage of deposition or cleaning gas therethrough. The faceplate 74 is typically made of metal to allow the application of a voltage or potential thereto and thereby serves as electrode 54a in the process chamber 52. A suitable faceplate 74 can be made of aluminum with an anodized coating.

A plurality of gas supplies, such as for example, the first and second gas supplies 80a,b, each provide a component of the process gas to the gas distributor 72. The gas supplies 80a,b each comprise a gas source 82a,b, one or more gas conduits 84a,b, and one or more gas valves 86a,b. For example, in one version, the first gas supply 80a comprises a first gas conduit 84a and a first gas valve 86a to deliver the fluorocarbon gas of the deposition gas, from the gas source 80a to a first inlet 78a of the gas distributor 72, and the second gas supply 80b comprises a second gas conduit 84b and a second gas valve 86b to deliver the dilution gas component from a second gas source 80b to a second inlet 78b of the gas distributor 72.

The process gas is energized in the process chamber 52 by coupling electromagnetic energy (e.g., high frequency voltage energy) to the gas in the process chamber 52 to form an energized gas which deposits material on the substrate 20 or cleans the process chamber 52. For example, process gas can be energized by applying a voltage between (i) a first electrode 54a of the substrate support 58 and substrate 20, and (ii) a second electrode 54b, which may be a surface of the gas distributor 72, ceiling 45, or chamber sidewall 46. The voltage applied across the pair of electrodes 54a,b capacitively couples energy to the process gas in the process zone 51 of the process chamber 52. Typically, the voltage applied to the electrodes 54a,b is an alternating voltage which oscillates at a radio frequency (RF).

A remote gas energizer 55 can also be disposed about the top of the chamber 52 and is fluidly coupled to the chamber 52 via a gas conduit 84c. The remote gas energizer 55 can be, for example, a cylinder 110 having a coil 112 wrapped around the cylinder 110 to inductively transfer RF energy to the gas passing through the cylinder. For example, the remote gas energizer 55 can be an Astron®-EX remote plasma source available from MKS Instruments, Andover, Mass. A power supply 108 is electrically coupled to the coil 112 of the remote gas energizer 55 to apply RF energy to the coil at a power level of from about 100 W to about 1000 W. The remote gas energizer 55 energizes a process gas, such as a cleaning gas, from a third gas supply 80c comprising one or more third gas sources 82c coupled to the remote gas energizer 55 and chamber 52 via the gas conduits 84c and gas valve 86c. The remotely energized cleaning gas can be used to periodically clean deposition residues from internal surfaces of the chamber 52. The energized reactive gas species are conveyed to the chamber interior through gas inlet 78c. Alternatively, the process gas passed through the remote gas energizer 55 can be energized using microwave energy supplied by a microwave generator (not shown).

The process chamber 52 also comprises a gas exhaust 90 to remove spent gas and byproducts from the process chamber 52 and maintain a predetermined pressure of deposition or treatment gas in the process zone 51. In one version, the gas exhaust 90 includes a pumping channel 92 that receives spent gas from the process zone 51, an exhaust port 94, a throttle valve 96 and one or more exhaust pumps 98 to control the pressure of gas in the process chamber 52. The exhaust pumps 98 may include one or more of a turbo-molecular pump, cryogenic pump, roughing pump, and combination-function pumps that have more than one function. The deposition gas pressure is controlled by controlling a gas exhaust 90, which is controlled by setting the opening size of a throttle valve 96 which connects an exhaust port 94 and piping from the process chamber 52 to an exhaust pump 98. The throttle valve 96 and various mass or volumetric flow meters can also be adjusted during the deposition process to keep the gas pressure and flow rates stable.

The process chamber 52 may also comprise an inlet port or tube (not shown) through the bottom wall 56 of the process chamber 52 to deliver a purging gas into the process chamber 52. The purging gas typically flows upward from the inlet port past the substrate support 58 and to an annular pumping channel. The purging gas is used to protect surfaces of the substrate support 58 and other chamber components from undesired deposition during the processing. The purging gas may also be used to affect the flow of gas in a desirable manner.

A controller 102 is also provided to control the operation and operating parameters of the process chamber 52. The controller 102 may comprise, for example, a processor and memory. The processor executes chamber control software, such as a computer program stored in the memory. The memory may be a hard disk drive, read-only memory, flash memory, or other types of memory. The controller 102 may also comprise other components, such as a floppy disk drive and a card rack. The card rack may contain a single-board computer, analog and digital input/output boards, interface boards, and stepper motor controller boards. The chamber control software includes sets of instructions that dictate the timing, mixture of gases, chamber pressure, chamber temperature, microwave power levels, high frequency power levels, support position, and other parameters of a particular process.

The process chamber 52 also comprises a power supply 104 to deliver power to various chamber components such as, for example, the first electrode 54a in the substrate support 58 and the second electrode 54b in the process chamber 52. To deliver power to the chamber electrodes 54a,b, the power supply 104 comprises a radio frequency voltage source that provides a voltage having the selected radio frequencies and the desired selectable power levels. The power supply 104 can include a single radio frequency voltage source, or multiple voltage sources that provide both high and low radio frequencies. The power supply 104 can also include an RF matching circuit. The power supply 104 can further comprise an electrostatic charging source to provide an electrostatic charge to an electrode which is often the electrostatic chuck of the substrate support 58. When a heater 68 is used within the substrate support 58, the power supply 104 also includes a heater power source that provides an appropriate controllable voltage to the heater 68. When a DC bias is to be applied to the gas distributor 72 or the substrate support 58, the power supply 104 also includes a DC bias voltage source that is connected to a conducting metal portion of the faceplate 74 of the gas distributor 72. The power supply 104 can also include the source of power for other chamber components, for example, motors and robots of the process chamber 52.

The process chamber 52 can also include one or more temperature sensors (not shown) such as thermocouples, RTD sensors, or interferometers to detect the temperature of surfaces such as component surfaces or substrate surfaces within the process chamber 52. The temperature sensor is capable of relaying its data to the chamber controller 102 which can then use the temperature data to control the temperature of the processing process chamber 52, for example, by controlling the resistive heating element in the substrate support 58.

Although exemplary embodiments of the present invention are shown and described, those of ordinary skill in the art may devise other embodiments which incorporate the present invention and which are also within the scope of the present invention. Furthermore, the terms below, above, bottom, top, up, down, first and second and other relative or positional terms are shown with respect to the exemplary embodiments in the figures and are interchangeable. Therefore, the appended claims should not be limited to the descriptions of the preferred versions, materials, or spatial arrangements.

What is claimed is:

1. A fluorocarbon coating comprising an amorphous structure with CF₂ bonds present in an atomic percentage of at least about 15%, and having a refractive index of less than about 1.4.

2. A coating according to claim 1 comprising a ratio of fluorine to carbon of from about 1 to about 2.

3. A coating according to claim 1 comprising CF, CF₃, and C—CF bonds.

4. A coating according to claim 1 formed by a method comprising:
(a) placing a substrate in a process zone;
(b) introducing a deposition gas comprising a fluorocarbon gas and a diluent into the process zone; and
(c) forming a capacitively coupled plasma of the deposition gas by coupling energy to the process electrodes in the process zone to deposit the fluorocarbon coating on the substrate.

5. A coated photo-active device comprising:
(a) a photo-active feature; and
(b) a fluorocarbon coating overlying the photo-active feature, the fluorocarbon coating comprising an amorphous structure with CF₂ bonds present in an atomic percentage of at least about 15%, and having a refractive index of less than about 1.4.

6. A CMOS image sensor comprising:
(a) a substrate;
(b) a photo-active feature on the substrate;
(c) one or more metal features about the photo-active feature;
(d) a lens overlying the photo-active feature; and
(e) a fluorocarbon coating on the lens.

7. An image sensor according to claim 6 wherein the fluorocarbon coating comprises an amorphous structure with CF₂ bonds present in an atomic percentage of at least about 15%, and having a refractive index of less than about 1.4.

8. An image sensor according to claim 6 formed by a method comprising:
(a) placing a substrate in a process zone;
(b) introducing a deposition gas comprising a fluorocarbon gas and a diluent into the process zone; and
(c) forming a capacitively coupled plasma of the deposition gas by coupling energy to the process electrodes in the process zone to deposit the fluorocarbon coating on the substrate.

9. A CMOS image sensor comprising:
(a) a substrate;
(b) an array of photo-active features on the substrate;
(c) twin stacks of metal features about each of the photo-active features;
(d) a color filter array comprising at least three different color filters disposed over the photo-active features;
(e) a plurality of lenses, each lens overlying a color filter; and
(f) a fluorocarbon coating on each lens.

10. An image sensor according to claim 9 wherein the fluorocarbon coating comprises an amorphous structure with CF₂ bonds present in an atomic percentage of at least about 15%, and having a refractive index of less than about 1.4.

11. An image sensor according to claim 10 that is a front-illuminated CMOS image sensor.

12. An image sensor according to claim 10 that is a back-illuminated CMOS image sensor.

13. A method of depositing a fluorocarbon coating on a photo-active feature on a substrate, the method comprising:
(a) forming a substrate having a plurality of photo-active features thereon;
(b) placing the substrate in a process zone comprising a pair of process electrodes;
(c) introducing a deposition gas comprising a fluorocarbon gas into the process zone; and
(d) forming a capacitively coupled plasma of the deposition gas by coupling energy to the process electrodes in the process zone to deposit the fluorocarbon coating on the substrate.

14. A method according to claim 13 wherein (b) comprises maintaining the substrate at a temperature of less than about 240° C.

15. A method according to claim 13 wherein in (c), the fluorocarbon gas comprises at least one of C₄F₈, C₄F₆, C₃F₈, and C₃F₆O.

16. A method according to claim 13 wherein in (c), the deposition gas comprises, argon, helium, or mixtures thereof.

17. A method according to claim 13 wherein in (c), the deposition gas is maintained at a pressure of from about 0.5 Torr to about 20 Torr.

18. A method according to claim 13 wherein in (d), RF energy is coupled to the process electrodes at a power level of from about 10 to about 2000 W.

19. A method according to claim 13 further comprising cleaning the process chamber by:
(e) removing the substrate from the process zone of the process chamber; and
(f) providing an energized cleaning gas in the process zone, the energized cleaning gas comprising an oxygen-containing gas.
